(19) United States
(12) Patent Application Publication
(10) Pub. No.: US 2026/0288010 A1
(43) Pub. Date: Sep. 24, 2026

(54) DEVELOPMENT METHOD FOR PATTERNING METAL OXIDE PHOTORESIST

(71) Applicant: Tokyo Electron Limited, Tokyo (JP)

(72) Inventors: Joshua Baillargeon, Albany, NY (US); Hamed Hajibabaeinajafabadi, Albany, NY (US)

(21) Appl. No.: 19/570,710

(22) Filed: Mar. 18, 2026

Related U.S. Application Data
(60) Provisional application No. 63/774,504, filed on Mar. 19, 2025.

(51) Int. Cl. G03F 7/36; G03F 7/42; H01J 37/32; H10P 76/40

(52) U.S. Cl. CPC G03F 7/36; G03F 7/427; H01J 37/32449; H10P 76/4083

(57) ABSTRACT

A method for processing a substrate includes receiving the substrate, the substrate including a metal oxide photoresist (MOR) layer disposed over an underlying layer, the MOR layer including an exposed MOR region having been exposed to an actinic radiation and an unexposed MOR region, and performing a gas development process for a first processing time, the gas development process including exposing the substrate to a processing gas at a first temperature to form a modified unexposed MOR region from the unexposed MOR region, the modified unexposed MOR region including an element of the processing gas. And the method further includes exposing the substrate to a plasma for a second processing time at a second temperature to remove the modified unexposed MOR region to form a patterned MOR mask, the plasma being formed from an etch gas and an additive gas.

### CROSS-REFERENCE TO RELATED APPLICATIONS

This application claims the benefit of U.S. Provisional Application No. 63/774,504, filed on Mar. 19, 2025, which application is hereby incorporated herein by reference.

### TECHNICAL FIELD

The present invention relates generally to a system and method for processing a substrate, and, in particular embodiments, to a system and method for developing a metal oxide photoresist layer using a dual development process comprising a gas development process and a plasma development process.

### BACKGROUND

In the semiconductor industry, photolithography is commonly used in the fabrication of integrated circuits, with metal oxide photoresists (MOR) emerging as a valuable material for advanced patterning processes due to their high resolution and etch resistance properties. Traditionally, photoresists are developed using wet chemical processes. However, gas-based development techniques have gained attention for their potential to achieve finer features and reduce pattern collapse. In gas development of MOR, a gas or vapor is used to selectively remove exposed or unexposed areas of the photoresist, creating the desired pattern. This process involves complex interactions between the development chemistry and the metal oxide components of the photoresist.

### SUMMARY

In accordance with an embodiment of this disclosure, a method for processing a substrate includes receiving the substrate on a substrate holder disposed in a processing chamber, the substrate including a metal oxide photoresist (MOR) layer disposed over an underlying layer, the MOR layer including an exposed MOR region having been exposed to an actinic radiation and an unexposed MOR region. The method further includes performing a gas development process for a first processing time in the processing chamber, the gas development process including exposing the substrate to a processing gas at a first temperature to form a modified unexposed MOR region from the unexposed MOR region, the modified unexposed MOR region including an element of the processing gas. And the method further includes, after performing the gas development process for the first processing time, exposing the substrate to a plasma for a second processing time at a second temperature in the processing chamber to remove the modified unexposed MOR region to form a patterned MOR mask, the plasma being formed from an etch gas and an additive gas.

In accordance with another embodiment of this disclosure, a method for processing a substrate includes receiving the substrate on a substrate holder disposed in a processing chamber, the substrate including a metal oxide photoresist (MOR) layer disposed over an underlying layer, the MOR layer including a first region and a second region. The method further includes performing a low-temperature gas development process for a first processing time in the processing chamber to form a modified region from the first region, the low-temperature gas development process including exposing the substrate to a processing gas at a first temperature, the processing gas interacting with the first region to form the modified region. And the method further includes, after performing the low-temperature gas development process for the first processing time, exposing the substrate to a plasma for a second processing time at a second temperature in the processing chamber to remove the modified region and remaining portions of the first region and to form a patterned MOR mask, the plasma being formed from an etch gas and an additive gas.

And in accordance with yet another embodiment of this disclosure, a system for processing a substrate includes a processing chamber, the processing chamber including a substrate holder, a top plate, a bottom plate, and a dielectric sidewall, a gas system coupled to the processing chamber through a gas inlet and a gas outlet, the gas system including a processing gas, an etch gas, and an additive gas. The system further includes a temperature control system coupled to the substrate holder, an RF source power supply electrically coupled to a helical electrode, an RF bias power supply electrically coupled to the substrate holder, and a controller coupled to the processing chamber, and a memory storing instructions to be executed in the controller. The instructions when executed cause the controller to receive the substrate on the substrate holder disposed in the processing chamber, the substrate including a metal oxide photoresist (MOR) layer disposed over an underlying layer, the MOR layer including an exposed MOR region having been exposed to an actinic radiation and an unexposed MOR region. The instructions when executed further cause the controller to perform a gas development process for a first processing time in the processing chamber, the gas development process including exposing the substrate to the processing gas at a first temperature to form a modified unexposed MOR region from the unexposed MOR region, the modified unexposed MOR region including an element of the processing gas. And the instructions when executed further cause the controller to, after performing the gas development process for the first processing time, expose the substrate to a plasma for a second processing time at a second temperature in the processing chamber to remove the modified unexposed MOR region to form a patterned MOR mask, the plasma being formed from the etch gas and the additive gas.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1F illustrate a substrate during various steps of a processing method that uses a dual development process to remove undesired portions of a metal oxide photoresist layer in accordance with an embodiment of this disclosure;

FIGS. 2A-2D illustrate plots comparing various aspects of a metal oxide photoresist layer for various parametrizations of a dual development process which may be used to determine process parameters in accordance with embodiments of this disclosure;

FIG. 3 is a flowchart illustrating the steps of a processing method comprising a dual development process to remove undesired portions of a metal oxide photoresist layer in accordance with an embodiment of this disclosure;

FIG. 4 is a system diagram of a processing system capable of implementing processing methods comprising a dual development process in accordance with an embodiment of this disclosure;

FIG. 5 is a flowchart illustrating a processing method that uses a dual development process to remove undesired portions of a metal oxide photoresist layer in accordance with an embodiment of this disclosure; and

FIG. 6 is a flowchart illustrating a processing method that uses a dual development process to remove undesired portions of a metal oxide photoresist layer in accordance with an embodiment of this disclosure.

### DETAILED DESCRIPTION OF ILLUSTRATIVE EMBODIMENTS

In advanced semiconductor manufacturing, metal oxide photoresist (MOR) patterning processes face multiple technical hurdles that limit production efficiency and device quality. Current gas development processes have limited control knobs comprising pressures, flow rates, and chuck temperatures. Additionally, current gas development processes using HBr at low temperatures face multiple challenges comprising throughput, heavy bromination of the MOR which may yield significant outgassing/Sn contamination and critical dimension (CD) drift post air break, and full removal of the MOR is a challenge when forming larger features which leads to undesirable residues. And further, current gas development processes using HBr at low temperatures may form an undesirable etch stop layer, where these challenges may be mitigated using additional time-consuming temperature cycling steps that significantly reduce manufacturing throughput. This etch stop layer formation also impacts pattern quality and dimensional control, particularly for increasingly smaller semiconductor features. Traditional development methods struggle to simultaneously achieve high selectivity between exposed and unexposed regions of the MOR while maintaining precise pattern dimensions and minimizing line edge roughness. Further, existing processes use complex temperature management protocols that extend processing time and reduce overall production efficiency, which is challenging while maintaining cost-effective operations. Current temperature cycling methods and gas pulsing methods to remove the etch stop layer create throughput bottlenecks in the manufacturing process, while maintaining the desired selectivity and pattern fidelity remains challenging with existing development techniques.

This disclosure introduces a dual development process that combines a low-temperature gas development process with a plasma development process comprising targeted plasma treatment using an etch gas (such as methane) and an additive gas having beneficial vibrational energy characteristics and beneficial limited EUV/VUV light emissions (such as nitrogen). This hybrid approach leverages the high selectivity benefits of low-temperature gas development processes while utilizing a plasma that has low EUV/VUV characteristics and utilizing the chemistry to effectively etch the undesired modified MOR, while passivating desired MOR features. For example, the limited light emissions of the nitrogen are beneficial while the CH₄ drives the etch, where the C removes O in MOR films, the H facilitates the etch and the CHₓ component may yield deposition that helps protect the exposed MOR films while etching the non-exposed. The plasma development process, particularly using N₂/CH₄, demonstrates a unique synergistic effect when combined with a gas development process, achieving selectivity ratios above 20:1 without using time-consuming temperature cycling steps to the challenges described above. This dual development process not only enhances throughput by executing the entire development in a single continuous process but also improves pattern quality in line edge roughness (LER) and line width roughness (LWR), while effectively preventing pattern scumming in larger features.

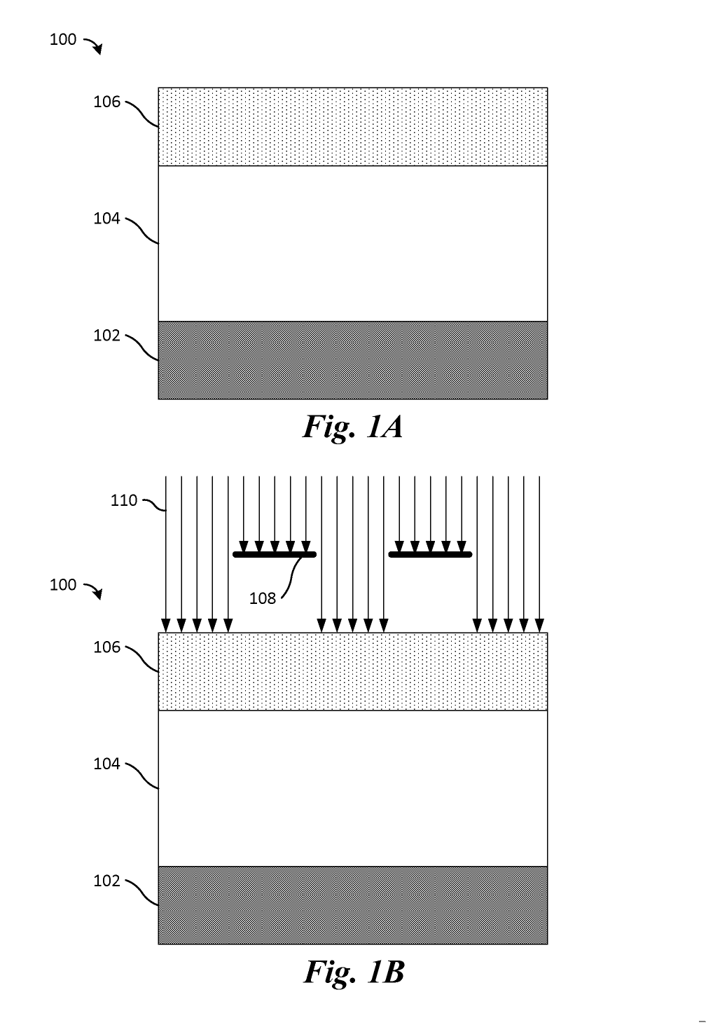

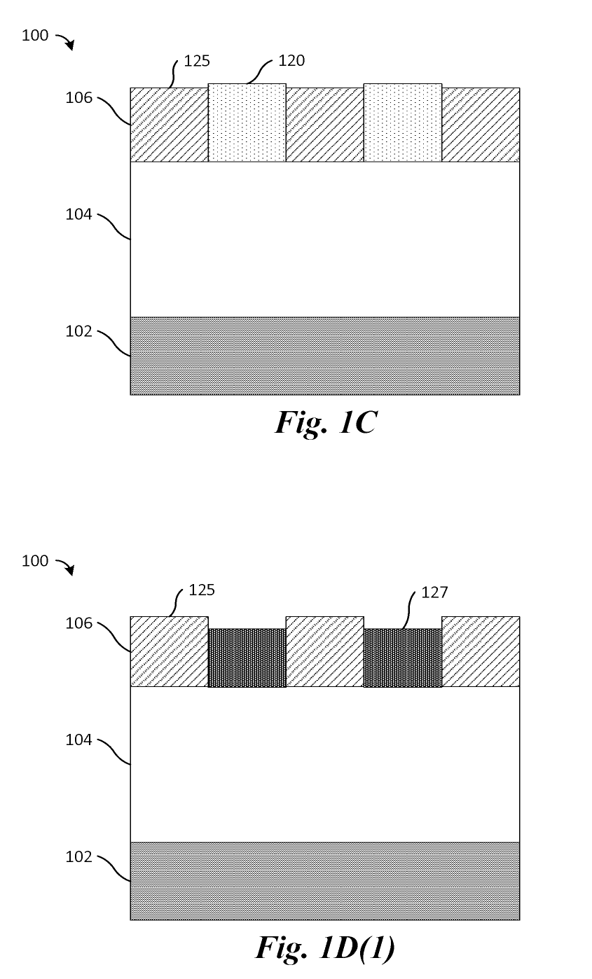

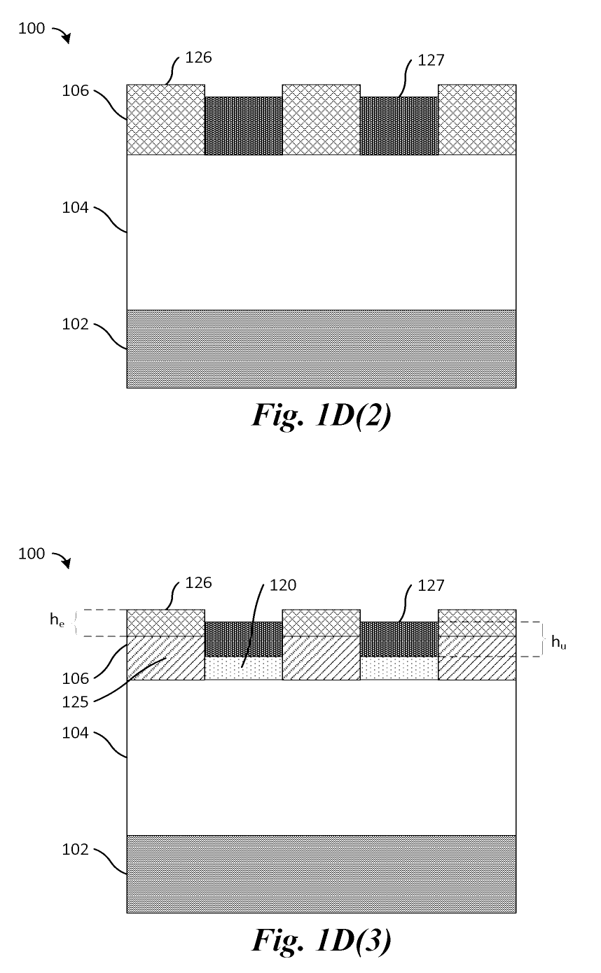

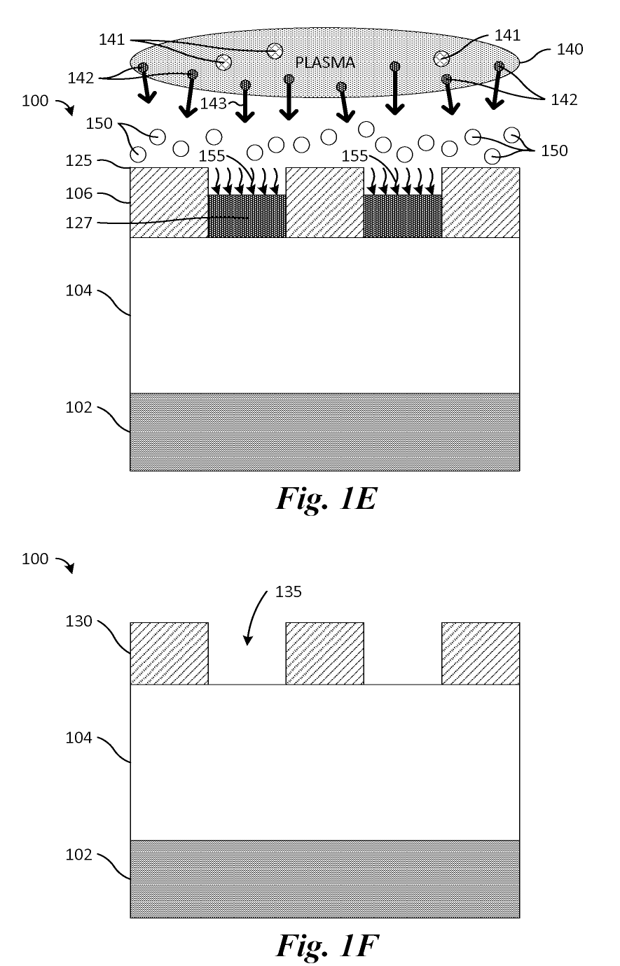

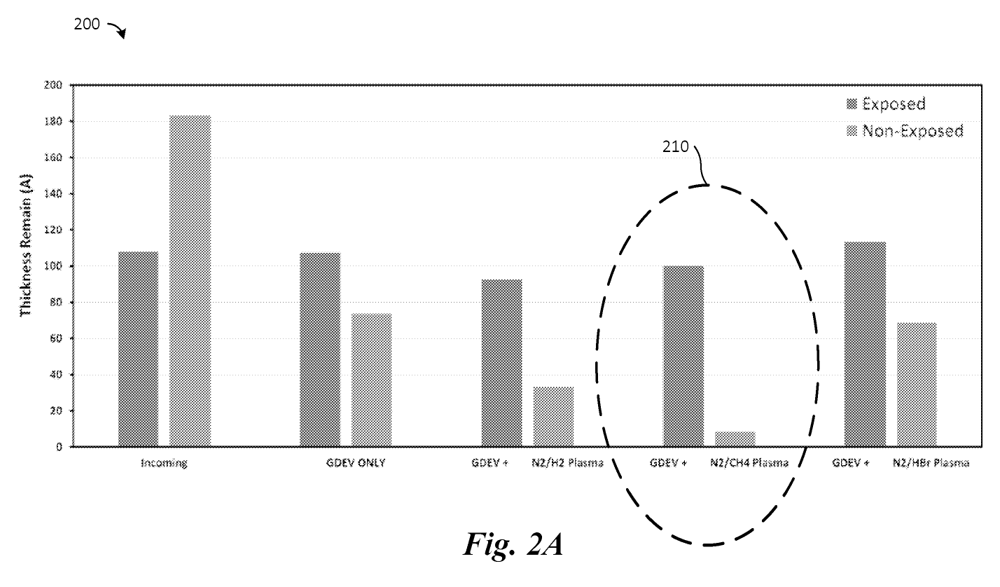

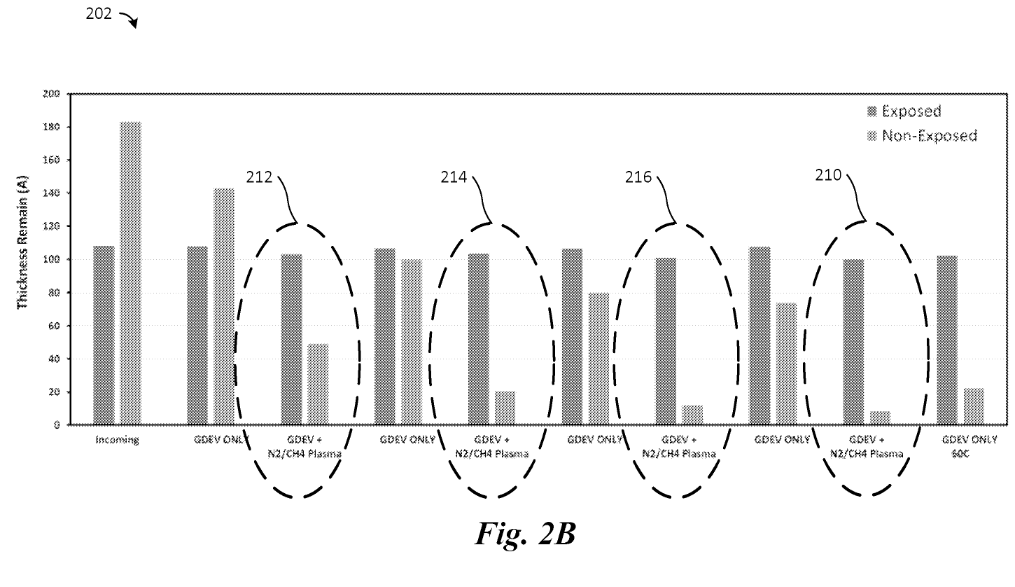

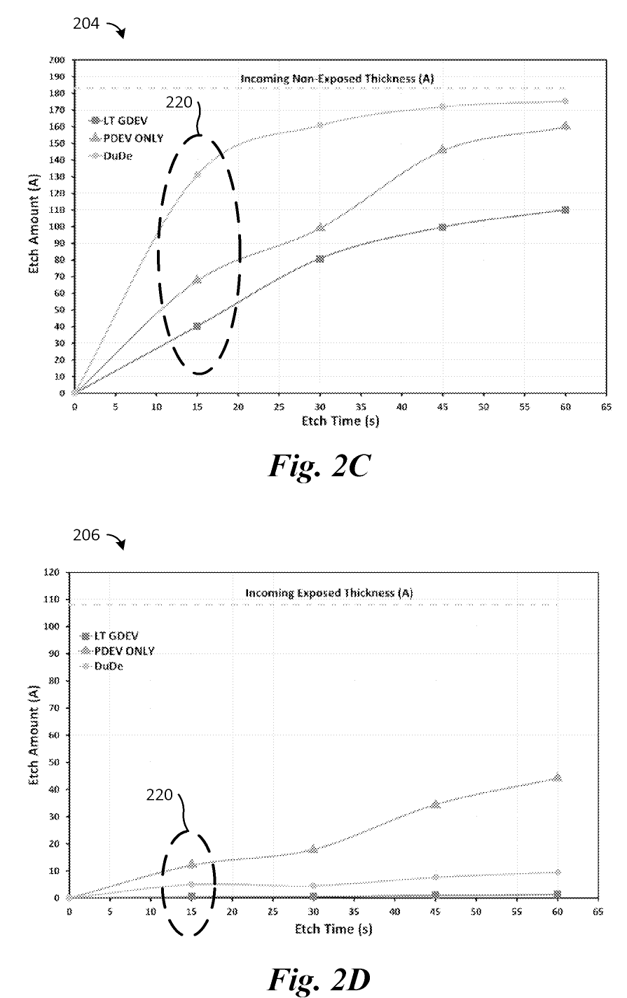

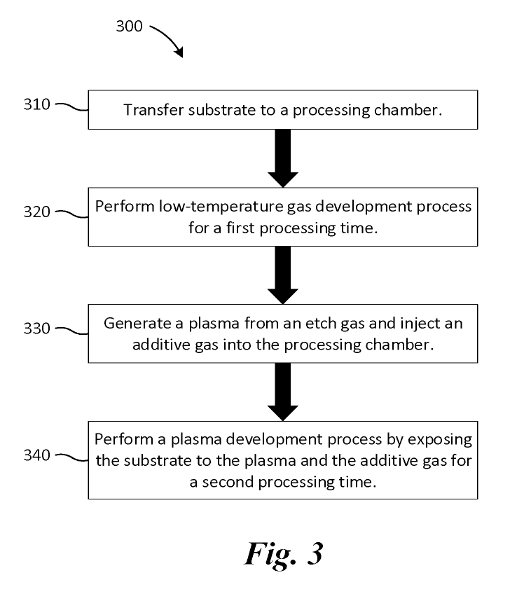

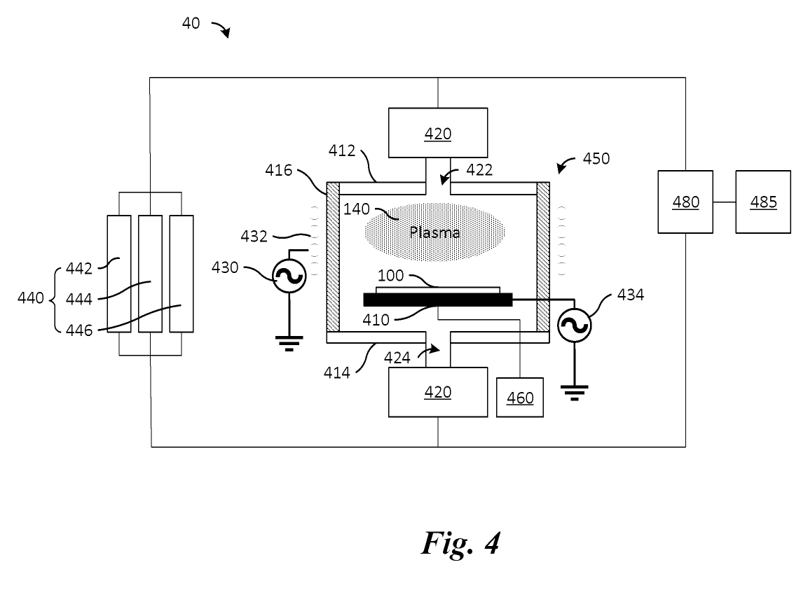

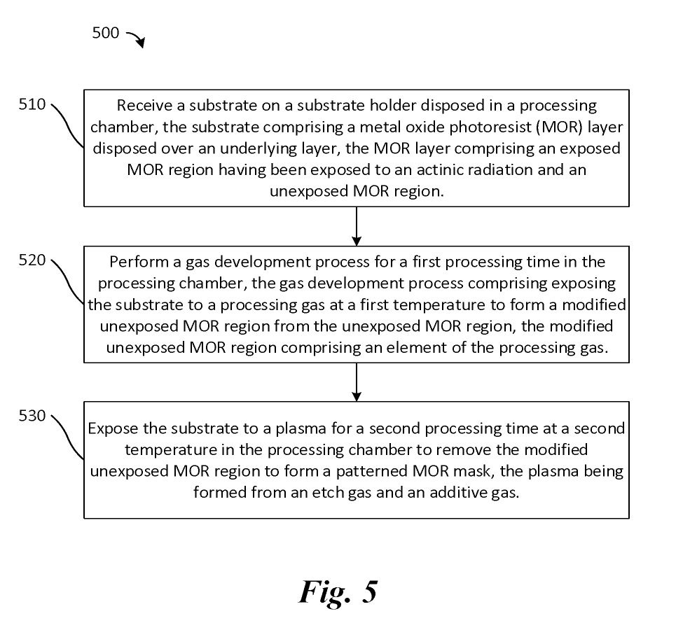

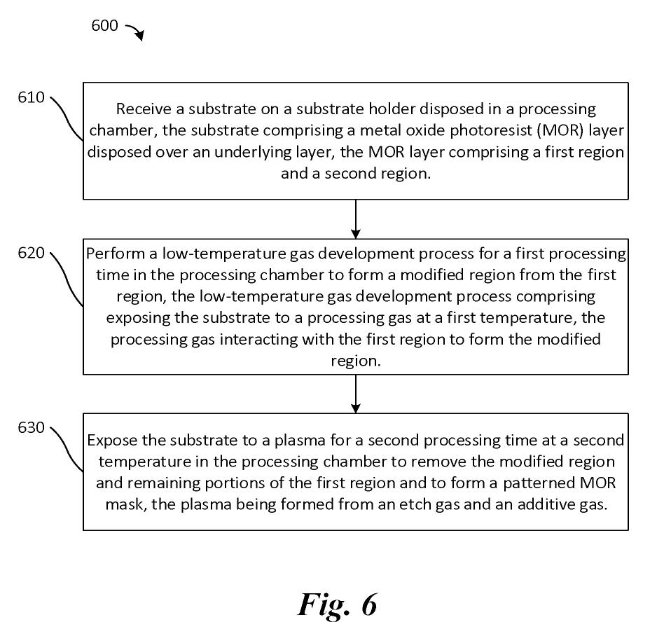

Embodiments provided below describe various methods, apparatuses and systems for processing a substrate, and in particular, to methods, apparatuses, and systems that may use a dual development process to remove undesired portions of a metal oxide photoresist (MOR) to form a patterned MOR mask. The following description describes the embodiments. FIGS. 1A-1F describe an example processing method that uses a dual development method to develop a negative tone metal oxide photoresist layer, the dual development method comprising a gas development process and a plasma development process. FIGS. 2A-2D are plots illustrating properties of a MOR layer after performing different processing methods that use different processing parameters in their respective dual development processes which may be used to determine process parameterizations. FIG. 3 is a flowchart used to describe the processing method comprising the dual development process of this disclosure. An example system capable of implementing the dual development process of this disclosure is described using FIG. 4. And the flowcharts of FIGS. 5-6 illustrate two other example processing methods comprising a dual development process for the removal of remaining portions of the metal oxide photoresist (MOR) layer in accordance with embodiments of this disclosure.

FIGS. 1A-1F illustrate a substrate 100 during various steps of a processing method that uses a dual development process to remove undesired portions of a metal oxide photoresist layer in accordance with an embodiment of this disclosure.

FIG. 1A illustrates a cross-sectional view of a substrate 100 which may be used in the processing method of this disclosure. The substrate 100 comprises a substrate base 102, an underlying layer 104 disposed over the substrate base 102, and a metal oxide photoresist (MOR) layer 106 disposed over the underlying layer 104. In an embodiment, the substrate 100 illustrated in FIG. 1A may be after receiving the substrate 100 in a photolithography tool to develop the MOR layer 106 using actinic radiation for example.

The underlying layer 104 and the MOR layer 106 may have been deposited through conventional deposition methods before the substrate 100 is received in the photolithography tool. For example, the underlying layer 104 may be deposited through a suitable deposition process such as a plasma deposition process, or an atomic layer deposition (ALD) process, or a chemical vapor deposition (CVD), or a plasma-enhanced chemical vapor deposition (PECVD) process. In various embodiments, after depositing the underlying layer 104, a planarization process may be performed to planarize the underlying layer 104 before depositing the MOR layer 106. Further, the MOR layer 106 may be deposited through a suitable deposition process for the MOR layer 106 such as a spin coating method, or gas phase deposition techniques such as an ALD/MLD process or a CVD process.

The substrate base 102 may comprise silicon, silicon oxide, or other suitable materials commonly used in semiconductor manufacturing. In various embodiments, the underlying layer 104 may comprise various materials depending on the specific application, such as dielectric materials, conductive materials, or semiconductor materials. For example, the underlying layer 104 may comprise a film stack for forming a memory device. In various embodiments, the underlying layer 104 may have a pattern transferred into it through a suitable etching process in subsequent processing steps. The MOR layer 106 comprises a photosensitive material that can be patterned through exposure to light, and subsequently used as a mask for further processing steps after patterning. In various embodiments, the MOR layer 106 comprises tin (Sn), oxygen/hydroxide (O/OH), oxygen (O), or organic components (saturated/unsaturated hydrocarbon). As an example, various embodiments of the MOR layer 106 comprise tin oxide, hafnium based MORs (such as hafnium oxide), zirconium based MORs (such as zirconium oxide), titanium based MORs (such as titanium oxide), or mixed metal MORs (such as hafnium zirconium oxide).

In various embodiments, the MOR layer 106 may be negative tone metal oxide photoresists, which may strengthen when exposed to patterning light comprising actinic radiation such that regions exposed to the patterning light are more difficult to remove. In other embodiments, the MOR layer 106 may be positive tone metal oxide photoresists, which may weaken when exposed to patterning light such that regions exposed to the patterning light are easier to remove. FIGS. 1A-1F illustrate embodiments where the MOR layer 106 comprises negative tone MOR.

As described above, the substrate 100 depicted in FIG. 1A may represent an initial stage in a photolithography process, where the MOR layer 106 is yet to be exposed to patterning light. This configuration forms the basis for subsequent processing steps, which may comprise exposure to actinic radiation, and a dual development process comprising a gas development process and a plasma development process (which may also be followed by etching) to create desired patterns on the substrate 100.

FIG. 1B illustrates the next step in the processing method, where conventional techniques are employed to expose the MOR layer 106 shown in FIG. 1A to light beams 110. In the step illustrated in FIG. 1B, a photo mask 108 is positioned above the substrate 100. The photo mask 108 comprises a predetermined pattern (feature pattern) that will be transferred to the MOR layer 106.

In various embodiments, light beams 110 are directed towards the photo mask 108. These light beams 110 may comprise ultraviolet (UV) light, extreme ultraviolet (EUV) light, or other suitable wavelengths depending on the photolithography process. For example, the light beams 110 may comprise actinic radiation suitable for causing desired chemical reactions in regions of the MOR layer 106 exposed to the light beams 110. In various embodiments where the light beams 110 comprise UV light, the photo mask 108 selectively blocks or allows the passage of light beams 110, creating a pattern of exposed and unexposed regions on the MOR layer 106. In other embodiments where the light beams 110 comprise EUV light, the photo mask 108 selectively reflects or allows the passage of light beams 110, creating the pattern of exposed and unexposed regions on the MOR layer 106.

The light beams 110 that pass through the photo mask 108 interact with the MOR layer 106, initiating photochemical reactions in the exposed regions. This interaction alters the chemical properties of the exposed regions, making them either stronger or weaker for a subsequent development process, depending on whether the MOR is a positive tone or negative tone resist. In the embodiment illustrated in FIG. 1B, the MOR layer 106 comprises negative tone MOR, which makes the exposed regions more difficult to remove after the exposure to the light beams 110.

The exposure time and intensity of the light beams 110 are carefully controlled to ensure proper patterning of the MOR layer 106. The precise control of these parameters helps achieve the desired resolution and fidelity of the pattern transfer process.

FIG. 1C depicts the substrate 100 following the light exposure of the previously unexposed MOR layer 106. This step illustrates the outcome of the photolithography process illustrated in FIG. 1B. The substrate 100 now comprises a patterned structure resulting from the selective light exposure of the MOR layer 106.

In one or more embodiments, the exposure to the patterning light in FIG. 1B formed a first region and a second region in the MOR layer, where the first region is an unexposed MOR region 120, and where the second region is an exposed MOR region 125. These exposed MOR regions 125 correspond to areas of the MOR layer 106 that were exposed to the light beams 110. The unexposed MOR regions 120 correspond to areas of the MOR layer 106 that were protected by the opaque parts of the photo mask 108 during the light exposure step.

The unexposed MOR regions 120 (the first regions) and exposed MOR regions 125 (the second regions) may be used to create a feature pattern on the substrate 100 that resembles the design of the photo mask 108 used in the previous step. In various embodiments, the feature pattern may represent features such as trenches, vias, or other structures suitable for the functionality of the final device. After the light exposure, a post exposure bake (PEB) may be performed using temperatures between 150˚C and 250˚C for a timeframe between 15s and 300s. Additionally, the PEB may be performed at pressures between 10mTorr and 10Torr in an inert gas atmosphere of Ar or N₂. In one or more embodiments, the PEB may be performed at atmospheric conditions.

After the exposure step described using FIGS. 1A-1C, the processing method develops the MOR layer 106 using a dual development process comprising a gas development process and a plasma development process to remove the first regions (the unexposed MOR regions 120) to form the feature pattern in the MOR layer 106, which is described using FIGS. 1D-1F below. The dual development process of this disclosure comprises the gas development method described using FIGS. 1D(1-3) and the plasma development process described using FIG. 1E below, and the hybrid nature of the dual development process reduces the processing time to develop the MOR layer 106. Further, the synergy between the gas development process and the plasma development process in the dual development process prevents etch stop layer formation, improves selectivity, mitigates scumming, enhances throughput, and creates opportunities for LER/LWR improvements.

FIG. 1D(1) illustrates the substrate 100 following a conventional gas development process applied to remove undesired portions of the MOR layer 106 by modifying the unexposed MOR regions 120. For example, the gas development process may comprise a low-temperature gas development process using a first temperature between -10˚C and 30˚C. This stage represents a further refinement of the feature pattern started in the previous photolithography steps where portions of the unexposed MOR regions 120 have been removed, but remnants, scumming, or byproducts of the unexposed MOR regions 120 remain. Further, the low-temperature gas development process modified the unexposed MOR regions 120 to form modified regions 127 (or modified unexposed MOR regions). Different amounts of scumming, remnants (remaining portions), or byproducts of the unexposed MOR regions 120 may remain after the gas development process based on the sizes of the features (such as their critical dimensions (CD)) in the desired feature pattern of the MOR layer 106. Additionally, various embodiments may form various thicknesses for the modified regions 127. In other embodiments, the gas development process may also modify the exposed MOR regions 125.

In various embodiments, the gas development process involves exposing the substrate 100 to a processing gas comprising a reactive gas or gas mixture. In various embodiments, the processing gas comprises organic acids (such as acetic acid) and inorganic Lewis acids (such as hydrogen halides comprising HBr) and/or Bronsted acid. In one or more embodiments, the processing gas comprises HI, HBr, HCl, or BCl₃. This processing gas interacts with the undesired portions of the MOR layer 106 to chemically alter (modify) a first region (or the unexposed MOR region 120) of the MOR layer 106, thus forming the modified regions 127 comprising altered selectivity which may be beneficial in further facilitating their removal from the substrate surface.

The process selectively targets the unexposed MOR regions 120 while leaving the exposed MOR regions 125 largely intact. The selectivity of the processing gas used in the gas development process enables the modification of both the exposed MOR regions 125 and unexposed MOR regions 120 to different degrees of modification as desired due to density, surface area, and chemical contrast. Though the gas development process uses a selective processing gas to modify portions of the MOR layer 106, the process may still remove/modify desired portions, just at a slower rate.

The gas development process results in a more defined feature pattern on the substrate 100. The exposed MOR regions 125 are now more prominent. In various embodiments, reactions of the selective processing gas with the unexposed MOR regions 120 may form the modified regions 127, which may comprise an element of the processing gas. For example, in an embodiment where the processing gas comprises HBr, the processing gas may brominate the unexposed MOR regions 120 to form the modified regions 127 comprising Br from the processing gas. Further, the modified regions 127 may have altered selectivity over the exposed MOR regions 125, thus enabling an improved selective removal of the modified regions 127 over the exposed MOR regions 125. The selectivity refers to removing the undesired portions of the MOR layer 106 at a faster rate than desired portions.

Conventional methods use gas development to fully remove the unexposed MOR regions 120, and then run an additional plasma step to descum to improve a defectivity margin and roughness. In some cases where low-temperature gas development methods are used and MORs exhibit etch stop layers, conventional processing methods for MOR layers perform a gas development step and then utilize a timely heating and cooling cycle or a gas pulsing to remove byproducts and etch stop layers formed so the MOR layer 106 may be fully processed. The processing method of this disclosure uses the gas development to modify the MOR layer 106 to enable a selective plasma etch and adds a plasma development process to remove the unexposed MOR regions 120 to form a patterned MOR mask without using the inefficient cyclic heating and cooling cycles and gas pulsing of conventional methods. Additionally, the plasma development process may also be used to remove any remnants of the unexposed MOR region 120 across features with different aspect ratios across the entire substrate 100 to fully reveal the underlying layer 104 and improve the fidelity of the feature pattern in the MOR layer 106.

During the gas development process, factors such as gas composition, pressure, temperature, and exposure time are carefully controlled to achieve optimal pattern resolution and minimize potential damage to the MOR layer 106. In various embodiments, the gas development process may be performed for a first processing time between 5s and 60s, with many embodiments using the first processing time between 10s and 30s. In one or more embodiments, the processing gas used may comprise an acid, HBr, HI, HCl, BCl₃, halogen-containing compounds, oxygen-based gases, or other reactive species depending on the specific chemistry of the MOR layer 106. In some embodiments, the processing gas may also comprise Ar, He, or N₂ as diluents. In other embodiments, the gas used may comprise nitrogen, hydrogen, and the gas may be exposed to the MOR layer 106 at a first temperature to chemically alter a surface region of the MOR layer 106 and form the modified regions 127. In embodiments where the modified region 127 is formed from the gas development process, the modified region 127 comprises an element from the processing gas that has reacted with the unexposed MOR regions 120.

This gas development step makes the patterned MOR layer easier to etch and react with a plasma by modifying the unexposed MOR regions 120 of the MOR layer 106 by halogenating and breaking bonds to form an intermediate species in the modified regions 127, which may be removed with higher selectivity than the exposed MOR regions 125. However, the gas development process described using FIG. 1D(1) may still leave some residues (such as byproducts) or result in incomplete development in certain areas (wide areas with low aspect ratio), which can affect subsequent processing steps. For example, as illustrated in FIG. 1D(1), the gas development process left portions of the unexposed MOR regions 120, and formed the modified regions 127.

When the unexposed MOR regions 120 or the modified regions 127 are not completely removed, defects may form in subsequent processing steps of the fabrication process, such as a subsequent etching step. To address these challenges, the processing method of this disclosure uses a dual development process comprising the gas development process and a plasma development process, where the plasma development process may remove remaining portions of the unexposed MOR regions 120 and remove the modified regions 127 or prevent the formation of etch stop layers in various embodiments.

In other embodiments, the processing gas used in the gas development process described using FIG. 1D(1) may also modify the exposed MOR regions 125 as well as the unexposed MOR regions 120. Such embodiments are described using FIGS. 1D(2) and 1D(3).

Now referring to FIG. 1D(2), the substrate 100 comprises the MOR layer 106 comprising modified regions 127 and second modified regions 126, where the modified regions 127 are formed from the processing gas modifying the unexposed MOR regions 120, and where the second modified regions 126 are formed from the processing gas modifying the exposed MOR regions 125. In this embodiment, both the unexposed MOR regions 120 and the exposed MOR regions 125 are modified by the processing gas, where the second modified regions 126 may be formed by the processing gas depositing an element in the exposed MOR regions 125. For example, the processing gas may brominate, halogenate, or hydrogenate the exposed MOR regions 125 to form the second modified regions 125 in various embodiments where the processing gas comprises HBr.

FIG. 1D(3) illustrates an embodiment where the gas development process modifies the unexposed MOR regions 120 to form the modified regions 127 up to an unexposed depth (hᵤ), and where the gas development process modifies the exposed MOR regions 125 to form the second modified regions 126 up to an exposed depth (hₑ). In various embodiments, the hᵤ may be different than hₑ, and the depths may be controlled through variations in the first processing time of the gas development process. In other embodiments, the hᵤ may be the same as hₑ. Further, the depths of the modified regions 127 and the second modified regions 126 may be controlled by varying processing parameters of the gas development process, such as by modifying gas flow rates or partial pressures of components of the processing gas.

In the embodiments illustrated in FIGS. 1D(2) and 1D(3), the second modified regions 126 may also have altered selectivity. The altered selectivity of the second modified regions 126 may still enable the selective removal of the modified regions 127 over the second modified regions 126 in various embodiments. After performing the gas development process described using FIGS. 1D(1-3), the method may proceed in the dual development process to the plasma development process, such as described using FIG. 1E below. In other embodiments, the modification to the MOR layer 106 formed by the gas development process may densify the MOR layer 106 or alter other properties of the MOR layer 106 to alter selectivity over different regions.

FIG. 1E depicts the substrate 100 undergoing a plasma development process designed to remove the modified regions 127 with higher selectivity which were formed by the gas development process illustrated in FIGS. 1D(1-3) and remove any remaining undesired portions of the unexposed MOR regions 120 to expose the underlying layer 104. This plasma development process is a refinement of the patterning process, aiming to achieve a cleaner and more precise pattern on the substrate surface and mitigate the challenges of conventional methods, such as challenges associated with inverse taper of MOR profile due to full removal by gas development, challenges associated with the formation and subsequent removal of etch stop layers, and challenges associated with heavy bromination of exposed areas which lead to outgassing and Sn contamination post air beak.

In various embodiments, the plasma development process employs a combination of specific chemistries and controlled environmental conditions to form a plasma 140 from an etch gas while simultaneously flowing an additive gas 150 over the substrate 100 to remove the modified regions 127 with higher selectivity (in reference to the plasma development process) and prevent the formation of the etch stop layers. This plasma development process forms a patterned MOR mask with improved definition and clarity. Further, the plasma development process may be performed in a separate processing chamber than the gas development process, such as the processing chamber described using FIG. 4. In other embodiments, the entire dual development method (the gas development process and the plasma development process) may be performed in the same processing chamber, such as the processing chamber described using FIG. 4.

The plasma development process forms the plasma 140 and subsequently exposes the substrate 100 to the plasma 140 and the additive gas 150 for a second processing time between 5s and 120s, where the second processing time may be shorter, longer, or the same as the first processing time. The plasma 140 comprises neutral species 141 and charged species 142 (as well as excited species) of the etch gas. A flow rate and partial pressure of the additive gas 150 may be controlled such that the additive gas 150 modifies (potentially through heat 155 or a limited EUV/VUV light production) the MOR layer 106 to form the modified regions 127 to enable the removal of the modified regions 127 using the plasma 140. Simultaneously, or subsequently, any remaining portions of the unexposed MOR regions 120 and the modified regions 127 are etched 143 rapidly using the neutral, ionized, or radical species of the plasma 140.

Plasmas emit light, which is why conventional development methods avoid using plasmas so that unexposed MOR regions are not chemically altered through exposure to light emitted by the plasma 140. The plasma development process of the dual development process of this disclosure synergistically balances effects between the additive gas 150 and the emitted light. Specifically, the emitted light may impart high degrees of vibrational energy to the additive gas 150, which may then be used to generate thermal energy and then interact with the byproducts or the modified regions 127 to heat 155 and subsequently remove the byproducts and/or modified regions 127. In one or more embodiments, the heat 155 may further alter the selectivity of the modified regions 127 over the regions desired to be kept in the MOR layer 106, such that the modified regions 127 are more easily removed and comprise higher selectivity by the plasma 140. In other embodiments, rather than the heat 155, the limited EUV/VUV light production by the additive gas 150 during the gas development process may further alter the selectivity of the modified regions 127 over the regions desired to be kept in the MOR layer 106. Additionally, to avoid over-exposing the unexposed MOR regions 120 to excessive light emitted form the plasma 140, the plasma development process may be performed over a small amount of time (or a second processing time which is shorter than the first processing time of the gas development process). In various embodiments, the second processing time may vary between 5s and 120s.

In an embodiment, the plasma development process may be performed in a controlled environment with specific temperature and pressure conditions, typically ranging from -30˚C to 30˚C and 10 mTorr to 600 mTorr, respectively. Further, flowrates and partial pressures of the additive gas and the etch gas may be controlled in real-time during the plasma development process to further improve pattern fidelity in the MOR layer 106, improve selectivity between exposed MOR regions 125 and modified regions 127, and improve etch rates of the modified regions 127. Additionally, the etching from the plasma development process may also mitigate scumming, which is another benefit of the processing method of this disclosure. In one or more embodiments, the processing gas comprises HBr, HI, HCl, or BCl₃, the additive gas comprises N₂, Ar, or He, and the etch gas comprises HBr, CH₄, Cl₂, C₂H₄, C₃H₈ (CₓH_{y} - hydrocarbons), BCl₃, H₂, or a combination of these.

FIG. 1E illustrates the plasma development process for an embodiment where the gas development process fully replaced the unexposed MOR regions 120 with the modified regions 127 such as described using FIG. 1D(1). Other embodiments may perform the same plasma development process described using FIG. 1E on the other embodiments described using FIGS. 1D(2-3) above, where the second modified regions 126 comprise altered selectivity that may advantageously enable the plasma 140 to etch the modified regions 127 at a higher etch rate than the second modified regions 126.

In some embodiments, the dual development process comprising the gas development process described using FIGS. 1D(1-3) and the plasma development process described using FIG. 1F may be cyclically performed as many times as desired to reveal the underlying layer 104 of the substrate 100.

FIG. 1F illustrates the substrate 100 after performing the plasma development process and the gas development process through the dual development method of this disclosure. The substrate 100 now comprises a patterned MOR mask 130 which may be used as an etch mask in subsequent processing steps to form a desired device, such as a semiconductor device or other forms of electronic or optical devices.

The patterned MOR mask 130 comprises the remaining portions of the exposed MOR regions 125 and now exhibits well-defined openings 135 that extend down to the underlying layer 104. These openings 135 correspond to the areas where the undesired MOR material has been completely removed, creating a clear path to the underlying layer 104. In one or more embodiments, the size and shape of these openings 135 closely match the intended pattern (feature pattern) from the original photo mask 108 used in the exposure step (FIG. 1B).

This dual development process addresses challenges associated with conventional gas development processes, such as incomplete development, residue formation, outgassing, and scumming (such as photoresist scumming). By modifying undesired portions of the MOR layer 106 with the gas development process to form modified regions 127 with altered selectivity to enable the plasma development process to thoroughly remove the residual MOR material and byproducts, the dual development process widens the defectivity window, improves pattern fidelity, and prepares the substrate 100 for subsequent processing steps, such as etching or material deposition. Additionally, through the complete removal of the remaining undesired MOR material and byproducts from the MOR layer 106, outgassing may be prevented, which also prevents contamination of other substrates in transfer to another processing chamber. Further, outgassing may also be prevented by minimizing the degree/amount of bromination/halogenation, which may be accomplished by minimizing the processing time of the gas development process to limit the amount of bromination/halogenation in the portion of the MOR layer 106 exposed during the gas development process.

Various parameters of the dual development process may be controlled in real-time to improve the selectivity of the dual development process, to control removal rates of the chemically altered regions or portions of the unexposed MOR regions 120, and to prevent removing excess material from the patterned MOR mask 130. For example, in various embodiments, the dual development process may simultaneously control, monitor, and recursively update parameters such as gas flow rates, gas concentrations, partial pressures of the various gases of the dual development process, chamber pressure of the processing chamber, temperatures of the substrate 100, gas flow rates into the processing chamber, and a first processing time of the gas development process and a second processing time of the plasma development process. For example, in one or more embodiments, a total processing time of the dual development process may depend on thicknesses of the MOR layer 106, and may vary between about 10s and about 120s. For example, the gas development process may comprise a first processing time between 15s and 30s, and the plasma development process may comprise a second processing time of approximately 15s. Further, a purge step may be performed between the gas development process and the plasma development process for approximately 30s in various embodiments.

In various embodiments, after performing the steps illustrated in FIGS. 1A-1F, subsequent processing steps may be performed to complete the device being fabricated from the substrate 100. For example, subsequent etching and depositing steps may be performed after transferring the substrate 100 to other processing chambers to finish forming the features from the feature pattern represented by the openings 135 in the patterned MOR mask 130. In various embodiments, the plasma development processing parameters may be determined based on a scan of the substrate 100 after the gas development process, such as by performing an exhaust OES to form a rough estimate of an amount of MOR modified based on back calculated molar amounts. The processing method may then use that topology to determine amounts of remnants or byproducts (such as the modified regions 127) in undesired regions of the MOR layer 106 to form the patterned MOR mask 130 comprising an improved pattern fidelity. FIGS. 2A-2D below illustrate plots collected using a large film of exposed and/or unexposed material and tracking the etch amounts as a result of thickness changes via ellipsometry which may be used to determine or modify processing parameters of the process recipe of the dual development process, such as process chemistry, processing times between gas development and plasma development processes, and gas development process and plasma process conditions such as gas pressures and flowrates used during either of the development processes.

FIG. 2A is a plot 200 illustrating remaining thicknesses of exposed and non-exposed regions (or unexposed regions) of a MOR layer for various processing methods comprising varying processing parameters in accordance with an embodiment of this disclosure. The remaining thicknesses (in angstroms) for both the non-exposed and the exposed regions of the MOR layer on an incoming substrate is illustrated on the far left of the plot 200. The remaining thicknesses for other processing methods that use different processing parameters are illustrated to the right of the remaining thicknesses for the incoming substrate.

Immediately to the right of the remaining thickness of the incoming substrate are the remaining thicknesses of both the non-exposed and the exposed regions of the MOR layer on a substrate that used a 60 second gas development process only (without using the plasma development process). And to the right of the gas development process remaining thicknesses is a processing parametrization that utilizes the dual development method of this disclosure. Specifically, a processing parametrization comprising a 60 second gas development process that is immediately followed by a 15 second plasma development process where the additive gas comprises nitrogen and the etch gas comprises hydrogen used to form the plasma.

A process 210 comprising a dual development process that utilizes a 60 second gas development process followed by a 15 second plasma development process illustrates an optimized process parameterization of the dual development process in comparison to the other process parametrizations. The additive gas used in the process 210 comprises nitrogen, and the etch gas comprises CH₄ which is used to form the plasma. Further, as illustrated by the remaining thicknesses of the exposed MOR regions and the non-exposed MOR regions, the process 210 advantageously uses the modification of the non-exposed MOR regions through bromination in the gas development process and properties of nitrogen (N₂) (such as a high vibrational energy or a limited EUV/VUV light production) and subsequently uses the plasma formed from the CH₄ etch gas to etch remaining portions of the modified non-exposed MOR regions. Additionally, as illustrated by the amount of remaining thickness of the non-exposed MOR regions compared to the exposed MOR regions, the process 210 offers high selectivity for the non-exposed MOR regions and may be used to form a patterned MOR mask with higher fidelity in comparison to conventional methods. In various embodiments, the 60 second gas development process may be the first processing time and the 15 second plasma development process may be the second processing time of the dual development process described in FIGS. 1A-1F.

Still referring to FIG. 2A, the plot 200 illustrates an additional process that utilizes a dual development process comprising a 60 second gas development process followed by a 15 second plasma development process, where the additive gas comprises nitrogen (N₂) and the etch gas comprises either H₂ or HBr which is used to form the plasma. As illustrated in the plot 200, each process that utilizes a dual development process removed more of the non-exposed MOR regions than the process that only used a conventional gas development method. In one or more embodiments, empirical data may be used to determine an optimized process parametrization for the dual development process of this disclosure, where various process parameters may be systematically varied and compared.

FIG. 2B illustrates a plot 202 of remaining thicknesses of exposed and non-exposed (or unexposed) regions of an MOR layer similar to the plot 200 of FIG. 2A. The difference between the plot 202 and the plot 200 is that the plot 202 illustrates more processing parameter variations than the plot 200. Further, the plot 202 illustrates the process 210 in comparison to other processes (212, 214, 216, and 218) which show variations in the first processing time for the gas development process to compare the preservation of the exposed MOR regions to the amount of non-exposed (or unexposed) MOR regions remaining. As illustrated in FIG. 2B, the process 210 shows the smallest amount of non-exposed (or unexposed) MOR regions in comparison to the amount of exposed MOR regions remaining.

FIGS. 2C-2D illustrate plots of the etch amounts of corresponding regions of an MOR layer for different process recipes. FIG. 2C illustrates a plot 204 of the etch amount on non-exposed (or unexposed) regions of an MOR layer. FIG. 2D illustrates a plot 206 of the etch amount on exposed regions of an MOR layer.

Now referring to FIG. 2C, the plot 204 illustrates a variation in etch amounts of the non-exposed regions of the MOR layer for variations in etch time (or processing time) where the squares illustrate a first series altering the gas development processing times (etch times) in an embodiment that only uses a gas development process. The triangles illustrate performing only the plasma development process for the etch time, and the circles (or dual development (DuDe)) illustrate performing the gas development for the associated etch time and then performing the plasma development for 15s for each data point.

And now referring to FIG. 2D, the plot 206 illustrates a variation in etch amounts of the exposed regions of the MOR layer for variations in etch time (or processing time) where the squares, triangles, and circles are as similarly described above in FIG. 2C. The plot 206 illustrates how the combination of the gas development process and the plasma development process may synergistically alter the selectivity of the exposed MOR regions in comparison to the etch amount of the non-exposed MOR regions illustrated in the plot 204.

As illustrated in FIGS. 2C-2D, a process 220 illustrates the advantageous synergistic effects of using the gas development process and the plasma development process in the dual development process to increase the etch amount for the non-exposed (or unexposed) MOR regions while preserving the exposed MOR regions of the MOR layer. Other embodiments comprising different materials may use FIGS. 2A-2D to determine optimized processing parametrizations for the dual development process.

FIG. 3 is a flowchart of a processing method 300 which uses a dual development process to modify regions of an MOR layer using a gas development step for improved selective removal during a plasma development step. The processing method 300 may begin in step 310. In step 310, the processing method 300 transfers the substrate to a processing chamber. For example, the substrate may be received on a substrate holder in the processing chamber, such as the processing chamber described for the steps of the dual development process illustrated in FIGS. 1D-1E above. The substrate described in step 310 may be the substrate 100 described in FIG. 1C, which is after a photolithography process was performed to develop the MOR layer 106 of the substrate 100.

In step 320, the processing method 300 performs a low-temperature gas development process for a first processing time using a processing gas to modify undesired regions of the MOR layer such that the undesired regions have enhanced removability based on a degree of bromination/halogenation from the processing gas which may be advantageously used to remove the modified regions using a plasma development step. In various embodiments where the MOR layer comprises positive tone resist, the low-temperature gas development process modifies exposed regions of the MOR layer. In other embodiments where the MOR layer comprises negative tone resist, the gas development process modifies unexposed regions of the MOR layer (such as described using FIGS. 1A-1F). In various embodiments, the low-temperature gas development process of step 320 may be the gas development process described using FIGS. 1D(1-3). In one or more embodiments, the low-temperature gas development method may be performed at a first temperature which may vary between -30˚ C. and 30˚ C. In one or more embodiments, the low-temperature gas development process may modify the unexposed MOR regions to form modified regions with altered selectivity, such as the modified regions 127 in FIGS. 1D(1-3).

Step 330 of the processing method 300 generates a plasma from an etch gas and injects an additive gas into the processing chamber. Step 330 may generate the plasma and inject the additive gas as similarly described for the plasma 140 and the additive gas 150 of FIG. 1E in an embodiment.

And step 340 of the processing method 300 performs a plasma development process by exposing the substrate to the plasma and the additive gas for a second processing time. In various embodiments, the plasma development process may be the same as described using FIG. 1E above. Further, the various process parameters of the dual development process may be controlled in real-time in various embodiments, where a controller may vary process parameters based on monitoring results of the dual development process.

In other embodiments, step 330 and 340 may be performed in a different processing chamber from the processing chamber used in the low-temperature gas development process of step 320. In those embodiments, the substrate may be transferred to a new processing chamber between step 320 and step 330.

The plasma development process of step 340 may use tailored gas mixtures to optimize chemical reactions and beneficially utilize additive gases to facilitate the subsequent removal of the modified regions or remaining unexposed MOR regions of the MOR layer. In various embodiments, the etch gas used to form the plasma in step 330 may be determined based on the material of the MOR layer. In one or more embodiments, the additive gas comprises nitrogen (N₂) and the etch gas comprises HBr, CH₄, ethane, propane, butane, Cl₂, H₂, or combinations of these. The plasma development process of step 340 may expose the substrate to the plasma and the additive gas while maintaining a temperature of the substrate, and controlling flow rates, pressures, partial pressures, and other processing parameters in the processing chamber to selectively remove remnants of the modified regions or undesired MOR regions remaining after the gas development process of step 320.

FIG. 4 illustrates a schematic diagram of a processing system 40, which may be used to perform the dual development process of this disclosure to form a patterned MOR mask. The processing system 40 comprises several components designed to achieve precise control over the dual development process.

The processing system 40 comprises a processing chamber 450 which houses the main processing components. In various embodiments, the processing chamber 450 may be a gas chamber configured to maintain a vacuum environment (or other process specifications) for the dual development process. Within the processing chamber 450, a substrate holder 410 is positioned to support the substrate 100 during the dual development process. In various embodiments, the substrate holder 410 may be coupled to a temperature control system 460 to control the temperature of the substrate 100 during the dual development process. In an embodiment, the substrate holder 410 comprises a vacuum chuck or an electrostatic chuck (ESC), and the temperature control system 460 comprises a resistive heater. In other embodiments, the substrate holder 410 and the temperature control system 460 may comprise cooling elements to further control the temperature of the substrate 100 as desired. In some embodiments, the heating and cooling elements may be parts of the processing chamber 450. In one or more embodiments, the substrate holder 410 may be any device suitable for holding the substrate 100 during the dual development process, and the substrate holder 410 may be conductive and electrically connected to a system ground (a reference potential). In the embodiment illustrated in FIG. 4, the substrate holder 410 is electrically coupled with an RF bias power supply 434 configured to bias the substrate 100 to process the substrate 100 using the plasma 140 as desired by the plasma process of this disclosure.

At the top of the processing chamber 450 is a top plate 412, and at the bottom is a bottom plate 414. The top plate 412 comprises a gas inlet 422 coupled to a gas flow control system 420 for introducing various gases into the processing chamber 450 from a gas system 440. The bottom plate 414 comprises a gas outlet 424 coupled to the gas flow control system 420 for evacuating various gases from the processing chamber 450. Additionally, the processing chamber 450 may comprise additional gas inlets and gas outlets besides the gas inlet 422 and the gas outlet 424. For example, as many gas inlets may be used for as many different gases are used to form the gas mixtures used in the dual development process. In some embodiments, as few as a single gas inlet may be used. In other embodiments, as many as ten gas inlets may be used. In various embodiments, a dielectric sidewall 416 of the processing chamber 450 is disposed proximal a helical electrode 432, where the helical electrode 432 is coupled to an RF source power supply 430 to generate the plasma 140 used to perform the plasma process of the dual development process of this disclosure.

In various embodiments, the top plate 412 may be a showerhead gas injection system having a gas distribution assembly, and one or more gas distribution plates or conduits coupled to the gas distribution assembly and configured to form one or more gas distribution plenums or supply lines. In further embodiments, the top plate 412 may comprise a branching gas distribution network designed to reduce or minimize gas distribution volume. The processing system 40 may be used to implement various embodiment dual development processes of this disclosure, such as in the processing methods described below using the flowcharts of FIGS. 5-6. Additionally, the processing system 40 may be capable of implementing the dual development process as previously described using FIGS. 1D-1E and 3 above.

The gas delivery of the processing system 40 is controlled by the gas system 440. This system manages the flow of various gases, such as a processing gas 442, an additive gas 444, and an etch gas 446. In one or more embodiments, these gases are combined to form the gas mixture used for the dual development process of this disclosure. Additionally, the various gases (442, 444, and 446) may be as described for the additive gas, processing gas, and etch gas in FIGS. 1A-1F above. In various embodiments, a purge gas may be provided by the gas system 440, such as an inert gas used to purge the processing chamber 450 during various steps of the dual development process of this disclosure. In various embodiments, the gas system 440 may be configured to supply as many different gases as desired and controlled using the gas flow control system 420 through the gas inlet 422 and evacuated through the gas outlet 424. The gas system 440 may comprise various components such as high-pressure gas canisters, valves (e.g., throttle valves), pressure sensors, gas flow sensors, vacuum pumps, pipes, and electronically programmable controllers. The gas system 440 may also be capable of regulating partial pressures of the gases entering the processing chamber 450 to be used in either the gas development process or the plasma development process of the dual development process.

In some embodiments, the processing chamber 450 may comprise a remote plasma generator or remote radical generator configured to supply the processing chamber 450 with excited, radical or metastable species, or combinations thereof for use in the plasma 140. In those embodiments, a power source may be used by the plasma generator or the remote radical generator to generate the excited, radical, or metastable species, or combinations thereof. Further, the RF source power supply 430 may be capable of supplying a source power between 50W and 200W.

The temperature of the dual development process may be regulated by the temperature control system 460, which works in conjunction with the heating and cooling elements of the processing chamber 450 or the substrate holder 410 to control the desired substrate temperature. For example, the temperature control system 460 may be capable of achieving temperatures between about -30˚C and 30˚C. In various embodiments, the processing chamber 450 can provide the first and second temperatures of the dual development process, where both the first and second temperature are between about -30˚C and 30˚C

The gas flow control system 420 may comprise various components such as high pressure gas canisters, valves (e.g., throttle valves), pressure sensors, gas flow sensors, vacuum pumps, pipes, and electronically programmable controllers. To control the pressure within the processing chamber 450, the processing system 40 uses the gas flow control system 420. This setup allows for precise control of the chamber pressure during the dual development process. For example, the dual development process may configure pressures within the processing chamber 450 between about 10 mTorr and about 800 mTorr.

The entire processing system 40 may be managed by a controller 480, which may be coupled to a memory 485. The controller 480 coordinates the operation of all system components, while the memory 485 stores process recipes, parameters, and other relevant data of the dual development process. The controller 480 and the memory 485 may be any suitable conventional device known in the art and capable of performing the functions described above.

By carefully controlling the gas flow rates through the different inlets and outlets, the characteristics of the various gases, substrate temperature, partial pressures of the components of the various gases of the dual development process, and chamber pressure, the processing system 40 can selectively remove undesired portions of the MOR layer with precisely controlled processing parameters and improved etch selectivity. Further, the dual development process may be capable of tailoring the MOR layer to remove remnants or undesired portions of the MOR layer to achieve the feature pattern desired to have been achieved by a previous photolithography step and form a patterned MOR mask which may be used as an etch mask in subsequent processing steps.

The processing system 40 illustrates an embodiment capable of generating an inductively coupled plasma (ICP), but the processing system 40 is one example only. In various embodiments, the processing chamber 450 may be configured to sustain a capacitively coupled plasma (CCP) with bias power applied to a top electrode. Alternatively, other suitable configurations such as electron cyclotron resonance (ESR) plasma sources and/or a helical resonator may be used. The RF source power supply 432 and the RF bias power supply 434 may be used to supply continuous wave (CW) or pulsed RF power to sustain the plasma, and may generate plasma power between 50W to 2000W. Gas inlets and outlets may be coupled to sidewalls of the processing chamber 450, and pulsed RF power sources and pulsed DC power sources may also be used in some embodiments. In various embodiments, the RF power, chamber pressure, substrate temperature, gas flow rates and other dual development processing parameters may be implemented in accordance with a respective process recipe for an embodiment of the dual development process of this disclosure.

FIGS. 5-6 are flowcharts illustrating example methods of processing a substrate in accordance with embodiments of the disclosure. The methods of FIGS. 5-6 may be combined with other methods and performed using the systems and apparatuses as described herein. For example, the methods of FIGS. 5-6 may be implemented in the processing system 40 of FIG. 4. Although shown in a logical order, the arrangement and numbering of the steps of FIGS. 5-6 are not intended to be limiting.

Referring to FIG. 5, step 510 of a method 500 of processing a substrate receives the substrate on a substrate holder disposed in a processing chamber, the substrate comprising a metal oxide photoresist (MOR) layer disposed over an underlying layer, the MOR layer comprising an exposed MOR region having been exposed to an actinic radiation and an unexposed MOR region. In various embodiments, the unexposed MOR region may correspond to the unexposed MOR regions 120 of FIGS. 1A-1F and the exposed MOR region may correspond to the exposed MOR regions 125 of FIGS. 1A-1F. Further, the substrate may be the substrate 100 of FIGS. 1A-1F where the MOR layer is the MOR layer 106 and the underlying layer is the underlying layer 104.

After, the method 500 performs a gas development process for a first processing time in the processing chamber in step 520. In step 520, the gas development process comprises exposing the substrate to a processing gas at a first temperature to form a modified unexposed MOR region from the unexposed MOR region, the modified unexposed MOR region comprising an element of the processing gas. In various embodiments, the gas development process of step 520 may be the gas development process described using FIGS. 1D(1-3) above, or as step 320 of the processing method 300 in FIG. 3 which performs a low-temperature gas development process. In one or more embodiments, the modified unexposed MOR region of step 520 may be the modified regions 127 of FIGS. 1D(1-3). In further embodiments, the element of the processing gas of the modified unexposed MOR region may be Br, or some other element of the elements present in the various embodiments of the processing gas.

Step 530 of the method 500 exposes the substrate to a plasma for a second processing time at a second temperature in the processing chamber to remove the modified unexposed MOR region to form a patterned MOR mask, where the plasma may be formed from an etch gas and an additive gas. Various parameters of the plasma development process in step 530 may be controlled in real-time, such as chamber pressures, partial pressures of the additive gas and the etch gas, flow rates of the additive gas and the etch gas, and the first and second temperatures.

In various embodiments, the modification by the low-temperature gas development process modifies the unexposed MOR region and forms a modified unexposed MOR region, which enables the plasma formed from the etch gas to etch the modified unexposed MOR regions to form a patterned MOR mask. The modified unexposed MOR region of step 530 may be the modified regions 127 of FIGS. 1D-1E, and the plasma development process of step 530 may be the plasma development process described using FIG. 1E in various embodiments. The combination of the gas development process in step 520 and the plasma development process in step 530 of the method 500 are the dual development method of this disclosure, which enables this hybrid development process to improve processing times. Further, the dual development process modifies regions of the MOR layer to enable control over the selectivity of various regions of the MOR layer, enabling controlled facilitated removal of undesired regions at higher rates than regions desired to form the patterned MOR mask.

Now referring to FIG. 6, step 610 of a method 600 of processing a substrate receives the substrate on a substrate holder disposed in a processing chamber, the substrate comprising a metal oxide photoresist (MOR) layer disposed over an underlying layer, the MOR layer comprising a first region and a second region. In various embodiments, the substrate may be the substrate 100 described using FIG. 1A, and the substrate of step 610 may be received in the processing chamber after performing the light exposure described using FIG. 1B.

In one or more embodiments, step 610 may be as described for step 310 of FIG. 3. Additionally, the processing chamber may be the processing chamber 450 of the processing system 40 of FIG. 4, and the method 600 may be performed in the processing system 40. Further, the underlying layer may be the underlying layer 104 and the MOR layer may be the MOR layer 106 of FIGS. 1A-1F. In an embodiment where the MOR layer comprises negative tone resist, the first region may be the unexposed MOR regions 120, and the second region may be the exposed MOR regions 125 of FIGS. 1A-1F. In other embodiments, the MOR layer may comprise positive tone resist, and the first region is the exposed MOR regions and the second region is the unexposed MOR regions.

After, in step 620, the method 600 performs a low-temperature gas development process for a first processing time in the processing chamber to form a modified region from the first region, the low-temperature gas development process comprising exposing the substrate to a processing gas at a first temperature, wherein the processing gas interacts with the first region to form the modified region. The low-temperature gas development process of step 620 may be the gas development process described using FIGS. 1D(1-3) or the low-temperature gas development process of step 320 of the processing method 300 in FIG. 3. Similarly, the processing gas may comprise HBr, or the other materials described for the gas development process in FIGS. 1D(1-3). In one or more embodiments, the modified region of step 620 may be the modified regions 127 formed from the unexposed MOR regions 120 in FIGS. 1D(1-3). In an embodiment, the first temperature may be achieved using the temperature control system 460 of FIG. 4.

In other embodiments, the exposure of the MOR layer to the processing gas may also modify the second region, such as described using FIGS. 1D(2-3) above. The formation of the modified regions by the exposure to the processing gas may deposit elements from the processing gas in the corresponding regions of the MOR layer, such as by brominating the first region. As a result, the modified region may comprise an altered selectivity over the second region, enabling the removal of the modified region at a different etch rate than the second region.

Still referring to FIG. 6, step 630 of the method 600 exposes the substrate to a plasma for a second processing time at a second temperature in the processing chamber to remove the modified region and remaining portions of the first region and to form a patterned MOR mask, where the plasma is formed form an etch gas and an additive gas.

In various embodiments, the patterned MOR mask may be the patterned MOR mask 130 of FIG. 1F. And in one or more embodiments, subsequent processing steps may be performed after step 630 to finish forming a device, such as by performing an etch process to transfer a feature pattern of the patterned MOR mask into the underlying layer of the substrate. Further, the plasma development process described in step 630 may be the plasma development process described in steps 330 and 340 of the processing method 300 of FIG. 3, or the plasma development process described using FIG. 1E above.

Example embodiments of the invention are described below. Other embodiments can also be understood from the entirety of the specification as well as the claims filed herein.

Example 1. A method for processing a substrate includes receiving the substrate on a substrate holder disposed in a processing chamber, the substrate including a metal oxide photoresist (MOR) layer disposed over an underlying layer, the MOR layer including an exposed MOR region having been exposed to an actinic radiation and an unexposed MOR region. The method further includes performing a gas development process for a first processing time in the processing chamber, the gas development process including exposing the substrate to a processing gas at a first temperature to form a modified unexposed MOR region from the unexposed MOR region, the modified unexposed MOR region including an element of the processing gas. And the method further includes, after performing the gas development process for the first processing time, exposing the substrate to a plasma for a second processing time at a second temperature in the processing chamber to remove the modified unexposed MOR region to form a patterned MOR mask, the plasma being formed from an etch gas and an additive gas.

Example 2. The method of example 1, further including, after exposing the substrate to the plasma for the second processing time, repeating the performing the gas development process for the first processing time and the exposing the substrate to the plasma for the second processing time to reveal the underlying layer.

Example 3. The method of one of examples 1 or 2, where the exposing the substrate to the plasma for the second processing time enables high vibrational energy species of the plasma to disrupt an etch stop layer formation.

Example 4. The method of one of examples 1 to 3, where the processing gas includes HBr, the additive gas includes nitrogen, the etch gas includes CH₄, and the element of the modified unexposed MOR region includes Br.

Example 5. The method of one of examples 1 to 4, where the processing gas includes HBr, HI, HCl, or BCl₃, where the additive gas includes N₂, Ar, or He, and where the etch gas includes HBr, CH₄, Cl₂, C₂H₄, C₃H₈ (CₓH_{y} - hydrocarbons), BCl₃, H₂, or a combination of these.

Example 6. The method of one of examples 1 to 5, where the first processing time varies between 5s and 120s, and the second processing time varies between 5s and 120s.

Example 7. The method of one of examples 1 to 6, where the gas development process includes a low-temperature gas development process, the first temperature varies between -30˚C and 30˚C, and the second temperature varies between -30˚C and 30˚C.

Example 8. The method of one of examples 1 to 7, where the second temperature is higher than the first temperature.

Example 9. The method of one of examples 1 to 8, where the etch gas of the plasma etches the modified unexposed MOR region to expose the underlying layer and form the patterned MOR mask.

Example 10. The method of one of examples 1 to 9, where the performing the gas development process forms a modified exposed MOR region from the exposed MOR region.

Example 11. A method for processing a substrate includes receiving the substrate on a substrate holder disposed in a processing chamber, the substrate including a metal oxide photoresist (MOR) layer disposed over an underlying layer, the MOR layer including a first region and a second region. The method further includes performing a low-temperature gas development process for a first processing time in the processing chamber to form a modified region from the first region, the low-temperature gas development process including exposing the substrate to a processing gas at a first temperature, the processing gas interacting with the first region to form the modified region. And the method further includes, after performing the low-temperature gas development process for the first processing time, exposing the substrate to a plasma for a second processing time at a second temperature in the processing chamber to remove the modified region and remaining portions of the first region and to form a patterned MOR mask, the plasma being formed from an etch gas and an additive gas.

Example 12. The method of example 11, where the MOR layer includes positive tone MOR, the first region includes MOR exposed to an actinic radiation, and the second region includes MOR unexposed to the actinic radiation.

Example 13. The method of one of examples 11 or 12, where the MOR layer includes negative tone MOR, the first region includes MOR unexposed to an actinic radiation, and the second region includes MOR exposed to the actinic radiation.

Example 14. The method of one of examples 11 to 13, where the MOR layer includes tin (Sn), oxygen (O), or organic components.

Example 15. The method of one of examples 11 to 14, where the etch gas of the plasma etches the modified region and the remaining portions of the first region to expose the underlying layer and form the patterned MOR mask.

Example 16. The method of one of examples 11 to 15, where the performing the low-temperature gas development process forms a second modified region from the second region.

Example 17. The method of one of examples 11 to 16, where the first temperature varies between -30˚C and 30˚C, the second temperature varies between -30˚C and 30˚C, the second temperature is higher than the first temperature, the first processing time varies between 5s and 120s, the second processing time varies between 5s and 120s, the processing gas includes HBr, the additive gas includes nitrogen, and the etch gas includes CH₄, H₂, or HBr.

Example 18. The method of one of examples 11 to 17, where the processing gas includes HBr, HI, HCl, or BCl₃, where the additive gas includes N₂, Ar, or He, and where the etch gas includes HBr, CH₄, Cl₂, C₂H₄, C₃H₈ (CₓH_{y} - hydrocarbons), BCl₃, H₂, or a combination of these.

Example 19. A system for processing a substrate includes a processing chamber, the processing chamber including a substrate holder, a top plate, a bottom plate, and a dielectric sidewall, a gas system coupled to the processing chamber through a gas inlet and a gas outlet, the gas system including a processing gas, an etch gas, and an additive gas. The system further includes a temperature control system coupled to the substrate holder, an RF source power supply electrically coupled to a helical electrode, an RF bias power supply electrically coupled to the substrate holder, and a controller coupled to the processing chamber, and a memory storing instructions to be executed in the controller. The instructions when executed cause the controller to receive the substrate on the substrate holder disposed in the processing chamber, the substrate including a metal oxide photoresist (MOR) layer disposed over an underlying layer, the MOR layer including an exposed MOR region having been exposed to an actinic radiation and an unexposed MOR region. The instructions when executed further cause the controller to perform a gas development process for a first processing time in the processing chamber, the gas development process including exposing the substrate to the processing gas at a first temperature to form a modified unexposed MOR region from the unexposed MOR region, the modified unexposed MOR region including an element of the processing gas. And the instructions when executed further cause the controller to, after performing the gas development process for the first processing time, expose the substrate to a plasma for a second processing time at a second temperature in the processing chamber to remove the modified unexposed MOR region to form a patterned MOR mask, the plasma being formed from the etch gas and the additive gas.

Example 20. The system of example 19, where the top plate includes a showerhead gas injection system including a gas distribution assembly.

Example 21. The system of one of examples 19 or 20, where the first temperature varies between -30˚C and 30˚C, the second temperature varies between -30˚C and 30˚C, the second temperature is higher than the first temperature, the first processing time varies between 5s and 120s, the second processing time varies between 5s and 120s, the processing gas includes HBr, the additive gas includes nitrogen, and the etch gas includes CH₄, H₂, or HBr.

Example 22. The system of one of examples 19 to 21, where the substrate holder includes a vacuum chuck or an electrostatic chuck (ESC).

Example 23. The system of one of examples 19 to 22, where partial pressures and flow rates of the additive gas, the etch gas, and the processing gas are adjusted in real-time by the gas system to control a removal rate of the modified unexposed MOR region.

While the inventive aspects are described primarily in the context of semiconductor manufacturing processes for metal oxide photoresist (MOR) development, it should also be appreciated that these inventive aspects may also apply to other lithography development processes and materials. In particular, aspects of this disclosure may similarly apply to development of various resist materials including organic resists, metal-containing resists, and other advanced patterning materials used in semiconductor device fabrication.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, embodiments include combinations of embodiments discussed in FIGS. 1A-1F, 3, and 5-6. It is therefore intended that the appended claims encompass any such modifications or embodiments.

What is claimed is:

1. A method for processing a substrate, the method comprising:
receiving the substrate on a substrate holder disposed in a processing chamber, the substrate comprising a metal oxide photoresist (MOR) layer disposed over an underlying layer, the MOR layer comprising an exposed MOR region having been exposed to an actinic radiation and an unexposed MOR region;
performing a gas development process for a first processing time in the processing chamber, the gas development process comprising exposing the substrate to a processing gas at a first temperature to form a modified unexposed MOR region from the unexposed MOR region, the modified unexposed MOR region comprising an element of the processing gas; and
after performing the gas development process for the first processing time, exposing the substrate to a plasma for a second processing time at a second temperature in the processing chamber to remove the modified unexposed MOR region to form a patterned MOR mask, the plasma being formed from an etch gas and an additive gas.

2. The method of claim 1, further comprising, after exposing the substrate to the plasma for the second processing time, repeating the performing the gas development process for the first processing time and the exposing the substrate to the plasma for the second processing time to reveal the underlying layer.

3. The method of claim 1, wherein the processing gas comprises HBr, the additive gas comprises nitrogen, the etch gas comprises CH₄ and the element of the modified unexposed MOR region comprises Br.

4. The method of claim 1, wherein the processing gas comprises HBr, HI, HCl, or BCl₃ wherein the additive gas comprises N₂ Ar, or He, and wherein the etch gas comprises HBr, CH₄ Cl₂ C₂H₄ C₃H₈ (CₓH_{y} - hydrocarbons), BCl₃ H₂ or a combination of these.

5. The method of claim 1, wherein the first processing time varies between 5s and 120s, and the second processing time varies between 5s and 120s.

6. The method of claim 1, wherein the gas development process comprises a low-temperature gas development process, the first temperature varies between -30˚C and 30˚C, and the second temperature varies between -30˚C and 30˚C.

7. The method of claim 1, wherein the second temperature is higher than the first temperature.

8. The method of claim 1, wherein the etch gas of the plasma etches the modified unexposed MOR region to expose the underlying layer and form the patterned MOR mask.

9. A method for processing a substrate, the method comprising:
receiving the substrate on a substrate holder disposed in a processing chamber, the substrate comprising a metal oxide photoresist (MOR) layer disposed over an underlying layer, the MOR layer comprising a first region and a second region;
performing a low-temperature gas development process for a first processing time in the processing chamber to form a modified region from the first region, the low-temperature gas development process comprising exposing the substrate to a processing gas at a first temperature, the processing gas interacting with the first region to form the modified region; and
after performing the low-temperature gas development process for the first processing time, exposing the substrate to a plasma for a second processing time at a second temperature in the processing chamber to remove the modified region and remaining portions of the first region and to form a patterned MOR mask, the plasma being formed from an etch gas and an additive gas.

10. The method of claim 9, wherein the MOR layer comprises positive tone MOR, the first region comprises MOR exposed to an actinic radiation, and the second region comprises MOR unexposed to the actinic radiation.

11. The method of claim 9, wherein the MOR layer comprises negative tone MOR, the first region comprises MOR unexposed to an actinic radiation, and the second region comprises MOR exposed to the actinic radiation.

12. The method of claim 9, wherein the MOR layer comprises tin (Sn), oxygen (O), or organic components.

13. The method of claim 9, wherein the etch gas of the plasma etches the modified region and the remaining portions of the first region to expose the underlying layer and form the patterned MOR mask.

14. The method of claim 9, wherein the first temperature varies between -30˚C and 30˚C, the second temperature varies between -30˚C and 30˚C, the second temperature is higher than the first temperature, the first processing time varies between 5s and 120s, the second processing time varies between 5s and 120s, the processing gas comprises HBr, the additive gas comprises nitrogen, and the etch gas comprises CH₄ H₂ or HBr.

15. The method of claim 9, wherein the processing gas comprises HBr, HI, HCl, or BCl₃ wherein the additive gas comprises N₂ Ar, or He, and wherein the etch gas comprises HBr, CH₄ Cl₂ C₂H₄ C₃H₈ (CₓH_{y} - hydrocarbons), BCl₃ H₂ or a combination of these.

16. A system for processing a substrate, the system comprising:
a processing chamber, the processing chamber comprising a substrate holder, a top plate, a bottom plate, and a dielectric sidewall;
a gas system coupled to the processing chamber through a gas inlet and a gas outlet, the gas system comprising a processing gas, an etch gas, and an additive gas;
a temperature control system coupled to the substrate holder;
an RF source power supply electrically coupled to a helical electrode;
an RF bias power supply electrically coupled to the substrate holder; and
a controller coupled to the processing chamber, and a memory storing instructions to be executed in the controller, the instructions when executed cause the controller to:
receive the substrate on the substrate holder disposed in the processing chamber, the substrate comprising a metal oxide photoresist (MOR) layer disposed over an underlying layer, the MOR layer comprising an exposed MOR region having been exposed to an actinic radiation and an unexposed MOR region,
perform a gas development process for a first processing time in the processing chamber, the gas development process comprising exposing the substrate to the processing gas at a first temperature to form a modified unexposed MOR region from the unexposed MOR region, the modified unexposed MOR region comprising an element of the processing gas, and
after performing the gas development process for the first processing time, expose the substrate to a plasma for a second processing time at a second temperature in the processing chamber to remove the modified unexposed MOR region to form a patterned MOR mask, the plasma being formed from the etch gas and the additive gas.

17. The system of claim 16, wherein the top plate comprises a showerhead gas injection system comprising a gas distribution assembly.

18. The system of claim 16, wherein the first temperature varies between -30˚C and 30˚C, the second temperature varies between -30˚C and 30˚C, the second temperature is higher than the first temperature, the first processing time varies between 5s and 120s, the second processing time varies between 5s and 120s, the processing gas comprises HBr, the additive gas comprises nitrogen, and the etch gas comprises CH₄ H₂ or HBr.

19. The system of claim 16, wherein the substrate holder comprises a vacuum chuck or an electrostatic chuck (ESC).

20. The system of claim 16, wherein partial pressures and flow rates of the additive gas, the etch gas, and the processing gas are adjusted in real-time by the gas system to control a removal rate of the modified unexposed MOR region.
